(19) United States
(12) Patent Application Publication
(10) Pub. No.: US 2026/0150606 A1
(43) Pub. Date: May 28, 2026

(54) SELF-ALIGNED CONTACT PATTERNING METHOD WITH USE OF AN ANTI-SPACER

(71) Applicant: Tokyo Electron Limited, Tokyo (JP)

(72) Inventors: David Power, Albany, NY (US); David Conklin, Saratoga Springs, NY (US)

(21) Appl. No.: 18/960,932

(22) Filed: Nov. 26, 2024

(51) Int. Cl. H01L 21/311; H01L 21/027; H01L 21/308; H01L 21/768; H01L 23/528

(52) U.S. Cl. CPC H10P 50/73; H10P 50/695; H10P 76/2041; H10W 20/069; H10W 20/089; H10W 20/43

(57) ABSTRACT

A method for manufacturing semiconductor devices can include forming an anti-spacer pattern including anti-spacer trenches, formed between a first patterned photoresist layer and a patterned overcoat layer, and extending along a first direction, forming a first patterned hard mask layer having first contact trenches extending along the first direction using the anti-spacer pattern, where the first patterned hard mask layer is formed from a first hard mask layer of underlying layers, forming a second patterned photoresist layer, where the second patterned photoresist layer includes contact-edge features and second contact trenches overlapping with the first contact trenches of the first patterned hard mask layer, where the contact-edge features and the second contact trenches extend in a second direction that is non-parallel with the first direction; and self-aligned etching using the second patterned photoresist layer and the first patterned hard mask layer to form third contact trenches.

### TECHNICAL FIELD

The present disclosure relates generally to methods for manufacturing semiconductor devices, and more particularly, self-aligned contact patterning using anti-spacer photoresist lithography in methods for manufacturing semiconductor devices.

### BACKGROUND

In photolithography for semiconductor manufacturing, a relief pattern can be topographical variation created on a surface of and/or through a photoresist material layer. A relief pattern can be formed when portions of a photoresist material layer are selectively exposed to light and then chemically developed, resulting in regions with different heights or levels, such as trenches and holes formed in and patterned in a layer of photoresist material. The photoresist material is a light-sensitive material that undergoes chemical changes when exposed to ultraviolet (UV) light or extreme ultraviolet (EUV) light (e.g., light with a wavelength of 13.5 nm). The photoresist material is typically exposed to a patterned light through a mask or directly using a laser. The pattern transferred to the photoresist material by exposure to light defines exposed areas and regions of the photoresist material.

In positive photoresist, the exposed regions become soluble and can be removed in a development process by chemicals of a developer solvent. In negative photoresist, the exposed regions become insoluble, and the unexposed areas can be removed in a development process by chemicals of a developer solvent. After exposure and pattern transfer, the wafer can be subjected to a chemical developer that dissolves the soluble parts of the photoresist to create a relief pattern on the surface of and/or through the photoresist material layer, such that the exposed (or unexposed) areas are removed, leaving behind patterned features. Then, this relief pattern can be used as a mask for further processing steps, such as etching or ion implantation, to transfer the pattern (design) into underlying layers and/or a substrate of the wafer.

As semiconductor manufacturing progresses to smaller technology nodes (e.g., 5 nm, 3 nm, and beyond), the limits of conventional photolithography present new challenges. Conventional photolithography at smaller scales at or near a limit of feature sizes possible with such techniques can result in patterns and features with poor critical dimension uniformity (CDU) and feature shapes that can be farther from ideal or desired shapes, which can affect critical dimensions (CD) and CDU of features patterned into and transfers to underlaying layers. Problems of poor CD and CDU can then affect device functionality (e.g., consistent resistance, capacitance, and induction characteristics), product performance and quality, and manufacturing yield.

Also, to achieve smaller feature sizes and tighter pitches, conventional photolithography is often combined with other techniques and tools outside of photolithography tools, such as tools for atomic layer deposition (ALD), etching, and cleaning, which can greatly increase manufacturing costs and complexity.

Thus, there is a need to improve photolithography techniques for achieving smaller feature sizes and tighter pitches for patterned photoresist while maintaining or improving CDU to facilitate progressions to smaller technology nodes while also reducing costs or at least lessening cost increases, and while reducing the number of tools and processing complexity needed to achieve such progressions to smaller technology nodes.

### SUMMARY

In accordance with an embodiment of the present disclosure, a method for manufacturing semiconductor devices can include: forming an anti-spacer pattern including anti-spacer trenches such that anti-spacer sidewalls of each of the anti-spacer trenches include a first anti-spacer sidewall defined by remaining first-patterned-photoresist-layer portions of a first patterned photoresist layer and a second anti-spacer sidewall defined by a patterned overcoat layer, where the anti-spacer trenches extend along a first direction, where the first patterned photoresist layer and the patterned overcoat layer are supported by a substrate, and where the substrate includes underlying layers; forming a first patterned hard mask layer having first contact trenches extending along the first direction using the anti-spacer pattern, where the first patterned hard mask layer is formed from a first hard mask layer of the underlying layers; forming a second patterned photoresist layer, where the second patterned photoresist layer includes contact-edge features and second contact trenches overlapping with the first contact trenches of the first patterned hard mask layer, where the contact-edge features and the second contact trenches extend in a second direction, and where the second direction is non-parallel with the first direction; and self-aligned etching using the second patterned photoresist layer and the first patterned hard mask layer to form third contact trenches.

In accordance with an embodiment of the present disclosure, a method for forming conductive contacts during manufacturing of semiconductor devices can include: forming an anti-spacer pattern including anti-spacer trenches such that anti-spacer sidewalls of each of the anti-spacer trenches include a first anti-spacer sidewall defined by remaining first-patterned-photoresist-layer portions of a first patterned photoresist layer and a second anti-spacer sidewall defined by a patterned overcoat layer, where the anti-spacer trenches extend along a first direction, where the first patterned photoresist layer and the patterned overcoat layer are supported by a substrate, and where the substrate includes underlying layers; forming a first patterned hard mask layer having first contact trenches extending along the first direction using the anti-spacer pattern, where the first patterned hard mask layer is formed from a first hard mask layer of the underlying layers; forming a second patterned photoresist layer, where the second patterned photoresist layer includes contact-edge features and second contact trenches overlapping with the first contact trenches of the first patterned hard mask layer, where the contact-edge features and the second contact trenches extend in a second direction, and where the second direction is non-parallel with the first direction; self-aligned etching using the second patterned photoresist layer and the first patterned hard mask layer to form third contact trenches; and depositing metal into the third contact trenches to form the conductive contacts.

In accordance with an embodiment of the present disclosure, a semiconductor device including conductive contacts can be formed using a method that can include: forming an anti-spacer pattern including anti-spacer trenches such that anti-spacer sidewalls of each of the anti-spacer trenches include a first anti-spacer sidewall defined by remaining first-patterned-photoresist-layer portions of a first patterned photoresist layer and a second anti-spacer sidewall defined by a patterned overcoat layer, where the anti-spacer trenches extend along a first direction, where the first patterned photoresist layer and the patterned overcoat layer are supported by a substrate, and where the substrate includes underlying layers; forming a first patterned hard mask layer having first contact trenches extending along the first direction using the anti-spacer pattern, where the first patterned hard mask layer is formed from a first hard mask layer of the underlying layers; forming a second patterned photoresist layer, where the second patterned photoresist layer includes contact-edge features and second contact trenches overlapping with the first contact trenches of the first patterned hard mask layer, where the contact-edge features and the second contact trenches extend in a second direction, and where the second direction is non-parallel with the first direction; self-aligned etching using the second patterned photoresist layer and the first patterned hard mask layer to form third contact trenches; and depositing metal into the third contact trenches to form the conductive contacts.

### BRIEF DESCRIPTION OF THE DRAWINGS

For a more complete understanding of example embodiments of the present disclosure, and the advantages thereof, reference is now made to the following descriptions taken in conjunction with the accompanying drawings, in which:

FIGS. 1A to 1E are cross-section views illustrating intermediate structures for forming a patterned mask layer;

FIGS. 1F to 1J are scanning electron microscopy (SEM) and/or transmission electron microscopy (TEM) images illustrating cross-sections of intermediate structures corresponding to the intermediate structures of FIGS. 1A to 1E, respectively;

FIG. 2 is a cut-away perspective view of an intermediate structure having the patterned mask layer of FIG. 1E;

FIGS. 3A to 3E are cross-section views illustrating intermediate structures for forming an anti-spacer pattern made using a method according to an embodiment of the present disclosure;

FIGS. 3F to 3J are SEM and/or TEM images illustrating cross-sections of intermediate structures corresponding to the intermediate structures of FIGS. 3A to 3E, respectively, made using a method according to an embodiment of the present disclosure;

FIG. 4 is a cut-away perspective view of an intermediate structure made using a method according to an embodiment of the present disclosure;

FIG. 5 is a cut-away perspective view of an intermediate structure made using a method according to an embodiment of the present disclosure;

FIG. 6 is a cut-away perspective view of an intermediate structure made using a method according to an embodiment of the present disclosure;

FIG. 7 is a cut-away perspective view of an intermediate structure made using a method according to an embodiment of the present disclosure;

FIG. 8 is a cut-away perspective view of an intermediate structure made using a method according to an embodiment of the present disclosure;

FIG. 9 is a cut-away perspective view of an intermediate structure made using a method according to an embodiment of the present disclosure;

FIG. 10 is a cut-away perspective view of an intermediate structure made using a method according to an embodiment of the present disclosure;

FIG. 11 is a cut-away perspective view of an intermediate structure made using a method according to an embodiment of the present disclosure;

FIG. 12 is a cut-away perspective view of an intermediate structure made using a method according to an embodiment of the present disclosure;

FIG. 13 is a cut-away perspective view of an intermediate structure made using a method according to an embodiment of the present disclosure;

FIG. 14 is a flowchart illustrating a method for manufacturing semiconductor devices according to an embodiment of the present disclosure;

FIG. 15 is a flowchart illustrating a method for forming conductive contacts during manufacturing of semiconductor devices according to an embodiment of the present disclosure;

FIG. 16 is a flowchart illustrating a method for forming conductive contacts during manufacturing of semiconductor devices according to an embodiment of the present disclosure; and

FIGS. 17A and 17B is a flowchart illustrating a method for forming conductive contacts during manufacturing of semiconductor devices according to an embodiment of the present disclosure.

### DETAILED DESCRIPTION OF ILLUSTRATIVE EMBODIMENTS

Referring now to the drawings, in which like reference numbers can be used herein to designate like or similar elements throughout the various views, illustrative and example embodiments are shown and described. The figures are not drawn to scale, and in some instances the drawings are exaggerated or simplified in places for illustrative purposes, including relative thicknesses and/or widths of layers and structures shown in the drawings. One of ordinary skill in the art can appreciate many possible applications and variations for other embodiments based on the following illustrative and example embodiments provided in the present disclosure.

In the present disclosure, terms such as “first”, “second”, “third”, “fourth”, and the like, can be used to describe various components, but the components are not necessarily limited by such terms, for example, regarding order, sequence, importance, or number of such components possible in an embodiment. Such terms can be used merely for the purpose of distinguishing one component from other components in a given embodiment or group of embodiments. Because semiconductor geometries and sizes can be so extremely small (e.g., on the order of 1 to 5 nm), the terms “film” and “layer” may be used interchangeably herein.

Ever continuous scaling can require improved patterning resolution. One approach is spacer technology to define a sub-resolution line feature via atomic layer deposition (ALD). One challenge, however, is that if the opposite tone feature is desired, using spacer techniques can involve a complex succession of operations, including over-coating with another material (an “overcoat”), using the spacer features as mandrels, chemical mechanical planarization (CMP), and reactive ion etch (RIE) to exhume the spacer material leaving a narrow trench, which can be costly. In such cases, spacer techniques can involve a complex and costly succession of steps, including over-coating with another material (an “overcoat”) using the spacer features as mandrels, chemical-mechanical planarization (CMP) to reveal the spacer features, and reactive ion etching (RIE) to remove the spacer material, leaving a narrow trench.

Anti-spacer technology is an alternate, self-aligned approach that can use the diffusion length of a reactive species across a boundary between an overcoat and an adjacent layer to define a critical dimension (CD), creating a narrow trench around the features of that adjacent layer after development of the overcoat or creating a narrow trench into the features of that adjacent layer after development of the diffusion changed regions. When generation of the reactive species is controlled spatially via exposure through a mask, finer features can be formed, such as a narrow slot contact. The CD itself can be tuned based on the physical and chemical properties of the reactive species (e.g., its molecular weight and affinity for interactions with the host material) and by modifying the bake temperature and bake time in a post exposure bake (PEB). As a result, anti-spacer techniques can enable patterning narrow slot-contact features at dimensions beyond the reach of advanced lithographic capabilities.

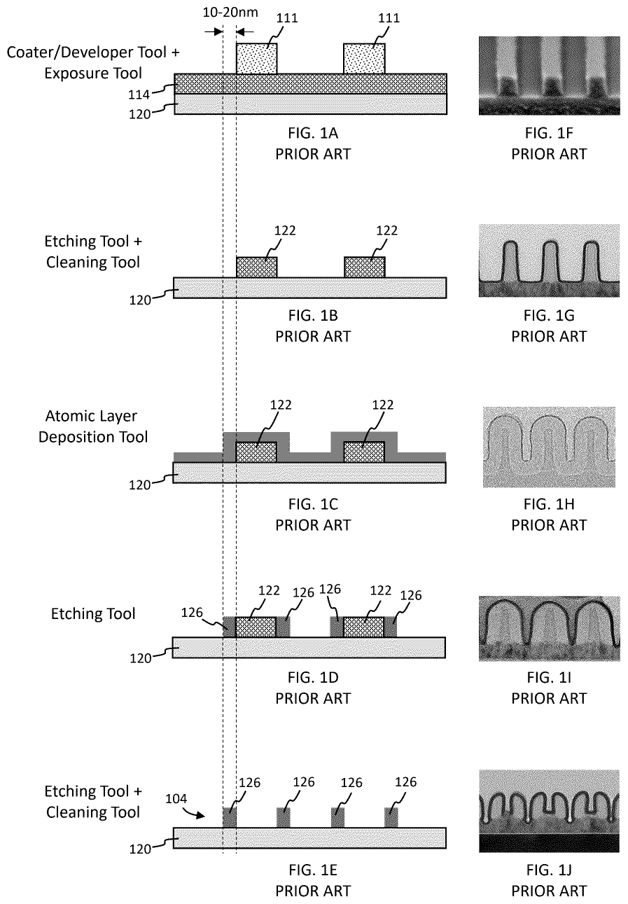

FIGS. 1A to 1J illustrate an example of a conventional method for making a patterned mask layer. FIGS. 1A to 1E are cross-section views illustrating intermediate structures for forming an intermediate patterned hard mask layer 104. FIGS. 1F to 1J are scanning electron microscopy (SEM) and/or transmission electron microscopy (TEM) images illustrating cross-sections of intermediate structures corresponding to the intermediate structures of FIGS. 1A to 1E, respectively.

Referring to FIGS. 1A and 1F, a patterned photoresist layer 111 can be formed on a hard mask layer 114 and a substrate 120. The patterned photoresist layer 111 can be formed using a coater/developer tool for depositing photoresist and removing photoresist material using a developer solvent after exposure of the photoresist material in a pattern using an exposure tool (e.g., extreme ultraviolet (EUV) light).

Referring to FIGS. 1B and 1G, the pattern of the patterned photoresist layer 111 can be transferred into the hard mask layer 114 to form a patterned hard mask layer 122, using an etching tool and a cleaning tool. As illustrated in FIG. 1G, the actual shape of the features of a patterned hard mask layer can be rounded and flared at the bottoms, which is already a departure from the rectangular shapes of the features of the patterned photoresist layer shown in FIG. 1F.

Referring to FIGS. 1C and 1H, a spacer layer 124 with a thickness in a range of 10 nanometers to 20 nanometers can be conformally deposited over the patterned hard mask layer 122 using atomic layer deposition (ALD) in an ALD tool. Because ALD can be highly conformal, the spacer layer 124 can have features with a shape closely matching the features of the patterned hard mask layer 122, by extending from the topography of the patterned hard mask layer 122, as illustrated in FIG. 1H for example. Accordingly, the rounded tops of the features of the patterned hard mask layer become rounded features having a larger radius for the spacer layer, as illustrated in FIG. 1H for example. One disadvantage of forming a spacer layer 124 using ALD is that the deposition process is very slow because the layer is built up by depositing a limited number of atoms at a time to provide uniform conformity and uniform thickness.

Referring to FIGS. 1D and 1I, the spacer layer 124 can be anisotropically-vertically etched (e.g., reactive ion etching (RIE)) in an etching tool to remove materials of the spacer layer 124 on horizontal surfaces to form pillars 126. In an actual intermediate structure, the resulting features can be rounded with flared bottoms, as illustrated in FIG. 1I for example.

Referring to FIGS. 1E and 1J, the patterned hard mask layer 122 can be removed using a selective etch using an etchant that etches the material of the patterned hard mask layer 122 much faster than it etches the pillars 126. During such selective etching, the etchant ideally removes the patterned hard mask layer 122 while leaving the remainder of the spacer layer 124 (i.e., the pillars 126) in place to form a patterned spacer layer including a set of pillars 126, as illustrated in FIG. 1E. However, the features of an actual patterned spacer layer can have rounded tops and flared bottoms with greater etching depth into the substrate (or underlying layer of the substrate) than an etching depth where the patterned hard mask layer was removed (or partially removed), as illustrated in FIG. 1J for example. A comparison of the actual patterned spacer layer shown in FIG. 1J and the targeted or ideal patterned spacer layer (set of pillars 126) shown in FIG. 1E shows that the actual patterned spacer layer has several departures in shape and uniformity from the targeted or ideal patterned spacer layer.

To form the pillars 126 of FIGS. 1E and 1J, up to nine different tools may be required including a coater/developer tool, an exposure tool, one to three etching tools, one or two cleaning tools, an ALD tool, and one or more wafer transport tools. Each time a different tool is used, the wafer will typically need to be loaded from a tool chamber into a boat, transported to another tool while in the boat using a wafer transport tool (and/or manually using personnel), and unloaded from the boat into another tool chamber. The transporting steps take time and care to prevent exposure to ambient air and/or to prevent collapse of or damage to features of a topography for an intermediate structure. Also, some tools are much more slow to operate and perform a given operation for the process flow than other tools, which can create an unwanted bottleneck in the manufacturing work flow. Furthermore, some tools are much more expensive to own and/or operate than other tools. Thus, adding more tools into a manufacturing work flow can reduce reliability and/or yield by adding complexity, and can increase manufacturing time and/or costs, all of which are typically undesired for a manufacturer of semiconductor devices.

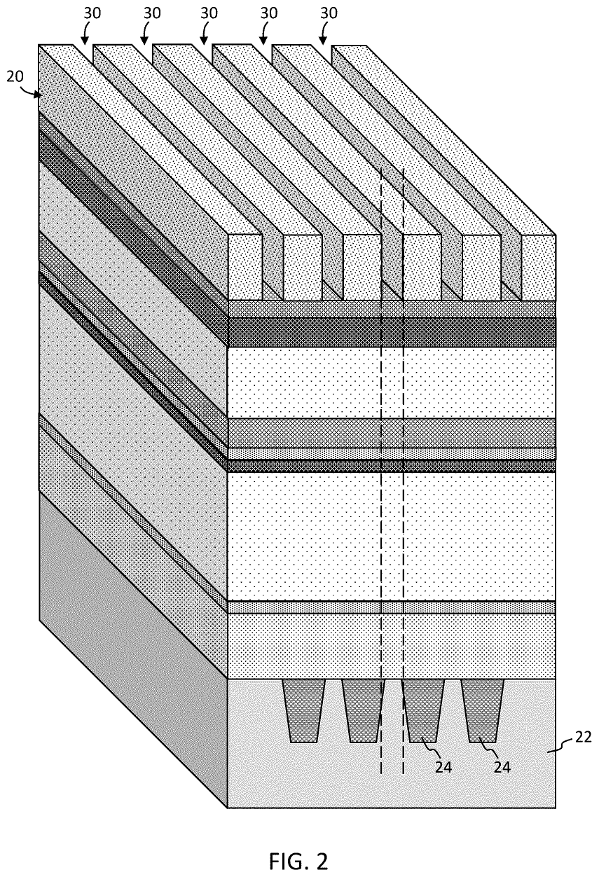

FIG. 2 is a cut-away perspective view of an intermediate structure having a patterned mask layer 20 on top of a substrate 22 in preparation for a self-aligned process for forming contacts for transistors 24 in the substrate 22, such as a fully self-align via (FSAV) process and/or such as a self-aligned middle-of-line (MOL) process, for example, which will be describe further below. FIG. 2 illustrates a potential use of a patterned mask layer 20 in that the trenches 30 of the patterned mask layer 20 are vertically aligned or registered with source and drain contact locations for the transistors 24.

To form the patterned mask layer 20 of FIG. 2 incorporating the conventional spacer method illustrated in FIGS. 1A to 1J, additional steps and operations would be needed to invert the pattern to convert the pillars 126 in FIG. 1E to trenches corresponding with the trenches 30 of the patterned mask layer 20 of FIG. 2. Thus, it would take using even more processing steps and changing tools than what was described above to achieve the pillars 126 of FIG. 1E to get to the trenches 30 of the patterned mask layer 20 of FIG. 2. And, as shown in FIG. 1J, the actual resulting features of the pillars 126 of FIG. 1E would typically be more rounded and the critical dimension uniformity (CDU) can be poor or unacceptable as the pitch becomes tighter and/or as the feature sizes are scaled to smaller geometries, which may not be sufficient or suitable regarding CDU as a starting point for forming the trenches 30 of the patterned mask layer 20 of FIG. 2. An embodiment of the present disclosure can be used to provide the patterned mask layer 20 for the intermediate structure shown in FIG. 2 and to improve upon results for such patterned mask layer 20 compared to that which could be provided by a conventional method (e.g., process flow including that of FIGS. 1A to 1E).

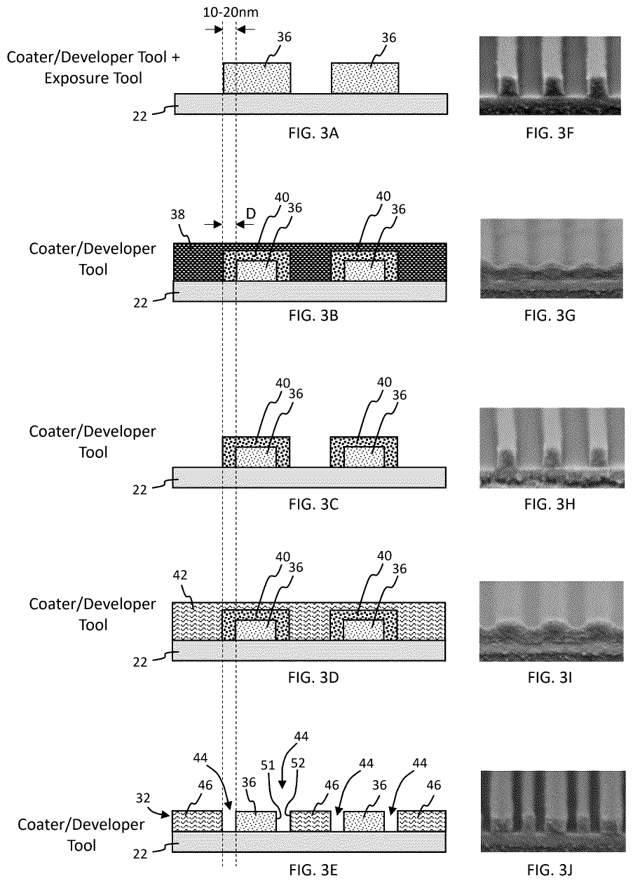

Some example embodiments of the present disclosure are described below with reference to FIGS. 3A-17B. Other embodiments can also be understood from the entirety of the specification as well as the claims herein.

As can be apparent from the description of example embodiments in the present disclosure, a patterned mask layer 20 of FIG. 2 with a resulting pitch and dimensions equivalent to that which could be provided by a convention method including the process flow of FIGS. 1A to 1J, for example, can be made using an embodiment of the present disclosure while having advantages including but not necessarily limited to: being made at a lower cost by using less tools; being made using tools that are less expensive to operate; being made faster; being made with a starting mask and/or a starting patterned photoresist layer that has larger features; being made to result in patterns and features having improved critical dimensions (CD); being made to result in patterns and features having improved critical dimension uniformity (CDU); being made to result in feature shapes that are closer to ideal or desired shapes, which can improve CD and CDU of features patterned into and transferred to underlaying layers and thereby can improve device functionality (e.g., consistent resistance, capacitance, and induction characteristics), product performance and quality, and manufacturing yield; being made to achieve smaller feature sizes and tighter pitches for patterned photoresist while maintaining or improving CDU to facilitate progressions to smaller technology nodes; being made while reducing or maintaining processing complexity to achieve progressions to smaller technology nodes; being made to result smaller feature sizes and tighter pitches than that of a starting mask and/or starting patterned photoresist layer; or any combination thereof, for example.

FIGS. 3A to 3E are cross-section views illustrating intermediate structures for forming an anti-spacer pattern made using a method according to an embodiment of the present disclosure. FIGS. 3F to 3J are SEM and/or TEM images illustrating cross-sections of intermediate structures corresponding to the intermediate structures of FIGS. 3A to 3E, respectively, made using a method according to an embodiment of the present disclosure.

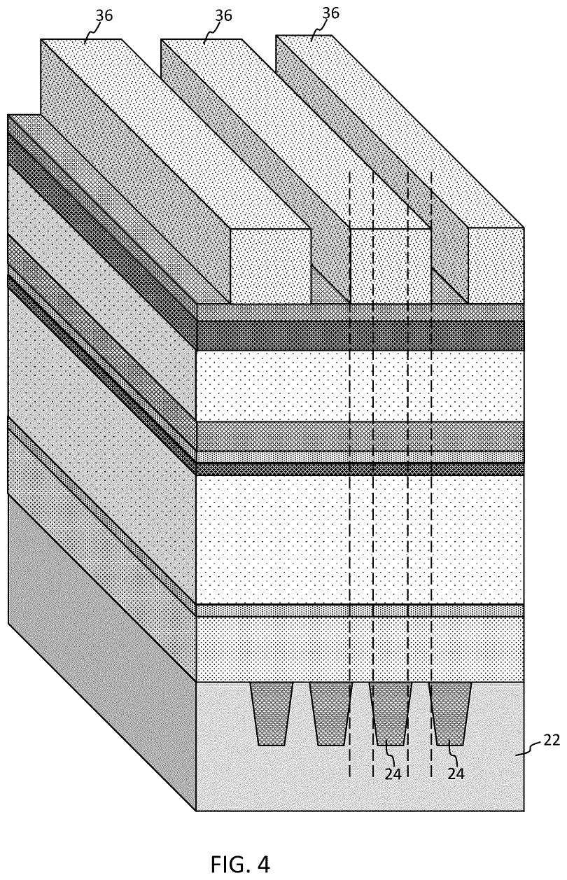

FIGS. 4 to 13 illustrate a method for forming conductive contacts using a self-aligned process during manufacturing of semiconductor devices according to an embodiment of the present disclosure. More specifically, FIGS. 4 to 13 illustrate that the method of forming an anti-spacer pattern illustrated in FIGS. 3A to 3J, for example, can be applied in and incorporated into a method for forming conductive contacts (or other middle-of-line (MOL) features) using a self-aligned process during manufacturing of semiconductor devices, according to an embodiment of the present disclosure. Thus, for example, FIGS. 3A to 3E can correlate with FIGS. 4, 6, 7, 8, and 9, respectively, with respect to forming a patterned mask layer 20 for use in a method for forming conductive contacts using a self-aligned process. Likewise, for example, FIGS. 3F to 3J can correlate with FIGS. 4, 6, 7, 8, and 9, respectively, with respect to forming a patterned mask layer 20 for use in a method for forming conductive contacts using a self-aligned process. Accordingly, for example, FIGS. 3A to 3E, FIGS. 3F to 3J, or FIGS. 4, 6, 7, 8, and 9, respectively, or any combination thereof, respectively, can be referred to while describing operations for forming an anti-spacer pattern 32 used as a patterned mask layer 20 according to an embodiment of the present disclosure (e.g., for the sake of being more concise and avoiding repetition of description).

Referring to FIGS. 3A to 3J, 4, and 6 to 9, an anti-spacer pattern 32 can be formed on a substrate 22 that includes underlying layers 34, and the anti-spacer pattern 32 can be vertically aligned with source and drain contact locations for transistors 24 in the substrate 22.

More specifically, referring to FIGS. 3A, 3F, and 4, a first photoresist layer of a first photoresist material can be formed on the substrate 22, and then the first photoresist layer can be patterned using a suitable photolithography technique (e.g., deep ultraviolet (DUV) photolithography, immersion lithography, extreme ultraviolet (EUV) photolithography, or high numerical aperture (NA) EUV photolithography) to form a first patterned photoresist layer 36. The first patterned photoresist layer 36 can be vertically registered with the source and drain contact locations for transistors 24 in the substrate 22, as an initial registration/alignment operation forming conductive contacts for the transistors using a self-aligned process.

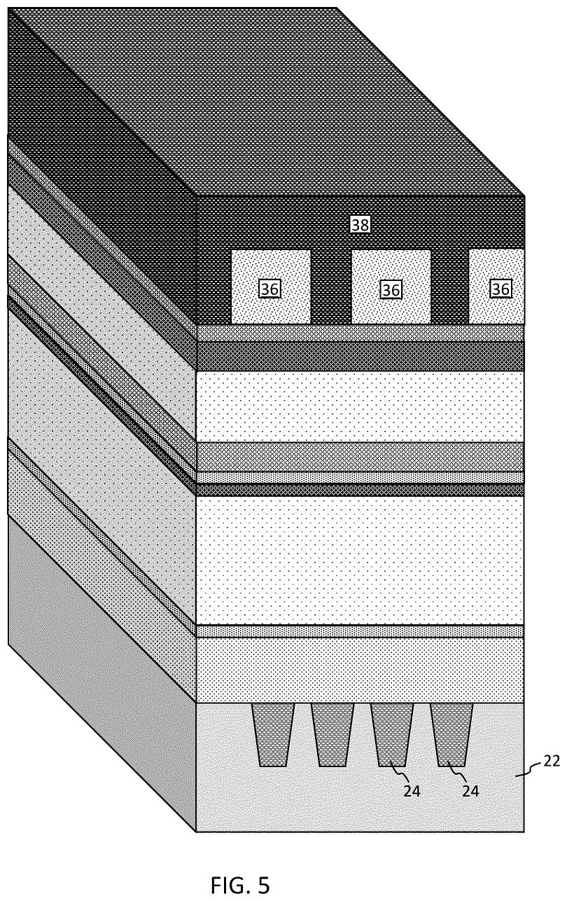

Referring to FIG. 5, a first overcoat layer 38 can be deposited over the first patterned photoresist layer 36.

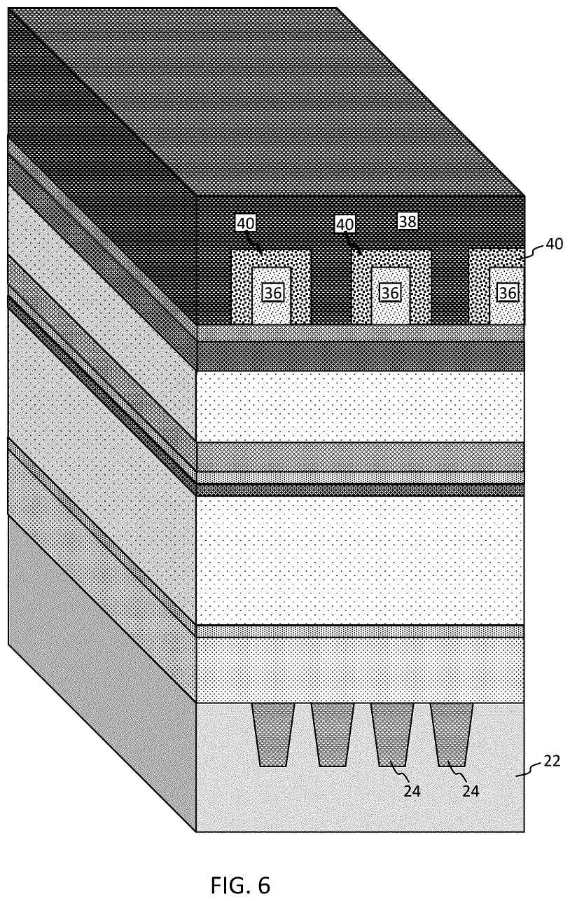

Referring to FIGS. 3B, 3G, and 6, outer regions of the first patterned photoresist layer 36 can be chemically transformed to anti-spacer regions 40 of a second photoresist material to a first depth D into the first patterned photoresist layer 36 using the first overcoat layer 38. The second photoresist material can be different than the first photoresist material after this chemical transformation such that the second photoresist material has a different solubility for a given developer than the first photoresist material. The first depth D can be in a range of 10 nanometers to 20 nanometers, for example. In some embodiments, the first depth D can be in a range of 8 nanometers to 40 nanometers, for example.

In an embodiment, the first patterned photoresist layer 36 and/or the first overcoat layer 38 can include an agent-generating ingredient that, in response to a suitable agent-activation trigger (e.g., heat and/or radiation), generates a solubility-changing agent (e.g., an acid). Example agent-generating ingredients can include a thermal-acid generator (TAG) that is configured to generate an acid in response to heat or a photo-acid generator (PAG) that is configured to generate an acid in response to actinic radiation.

For example, the chemically transforming of the outer regions of the first patterned photoresist layer 36 can include diffusing acid from the first overcoat layer 38 into the outer regions of the first patterned photoresist layer 36 to increase solubility of the outer regions for a given developer such that the outer regions become the anti-spacer regions 40.

For example, the first overcoat layer 38 can include a free acid as a solubility-changing agent. During a baking operation, the free acid can diffuse into perimeter portions of the first patterned photoresist layer 36 and can cause the perimeter portions of the first patterned photoresist layer 36 to become soluble in a given developer, where the original material (untransformed remaining portions) of the first patterned photoresist layer 36 is not soluble or is orders of magnitude less soluble to the given developer.

As another example, the first overcoat layer 38 can include a TAG as an agent-generating ingredient. Baking the wafer can cause the TAG to generate a solubility-changing agent (e.g., acid), which can be referred to as activating the acid, and the baking can also cause the generated solubility-changing agent to diffuse into perimeter portions of the first patterned photoresist layer 36 and can cause the perimeter portions of the first patterned photoresist layer 36 to become soluble in a given developer, where the original material (untransformed remaining portions) of the first patterned photoresist layer 36 is not soluble or is orders of magnitude less soluble to the given developer.

As another example, the first overcoat layer 38 can include a PAG as an agent-generating ingredient. The first overcoat layer 38 can be exposed to a radiation (e.g., actinic radiation) that can be performed prior to baking the wafer. Such exposure to radiation can cause the PAG to generate a solubility-changing agent (e.g., acid), which can be referred to as activating the acid. Then, baking of the wafer can cause the generated solubility-changing agent to diffuse into perimeter portions of the first patterned photoresist layer 36 and can cause the perimeter portions of the first patterned photoresist layer 36 to become soluble in a given developer, where the original material (untransformed remaining portions) of the first patterned photoresist layer 36 is not soluble or is orders of magnitude less soluble to the given developer.

In an embodiment, a baking process for forming the anti-spacer regions 40 can be a thermal process that is performed by heating the wafer in a process chamber to a temperature between 50° C. and 250° C., for example, or between 60° C. and 140° C. in certain embodiments, in vacuum or under a gas flow. In a particular example, the wafer can be baked for a duration in a range from 1 to 3 minutes. The bake conditions can be selected to promote the diffusion of the solubility-changing agent (and possibly generation of the solubility-changing agent from an agent generating ingredient of first overcoat layer 38 and/or in the first patterned photoresist layer 36, if applicable) and associated change in solubility of the perimeter regions of the first patterned photoresist layer 36 (see, e.g., FIGS. 3B and 6) to a target first depth D. The first depth D can be tuned by parameters of the baking process (such as, for example, a bake temperature and a bake duration) and material parameters (such as, for example, a polymer composition of the first patterned photoresist layer 36, and an acid composition and an acid concentration in the first overcoat layer 38).

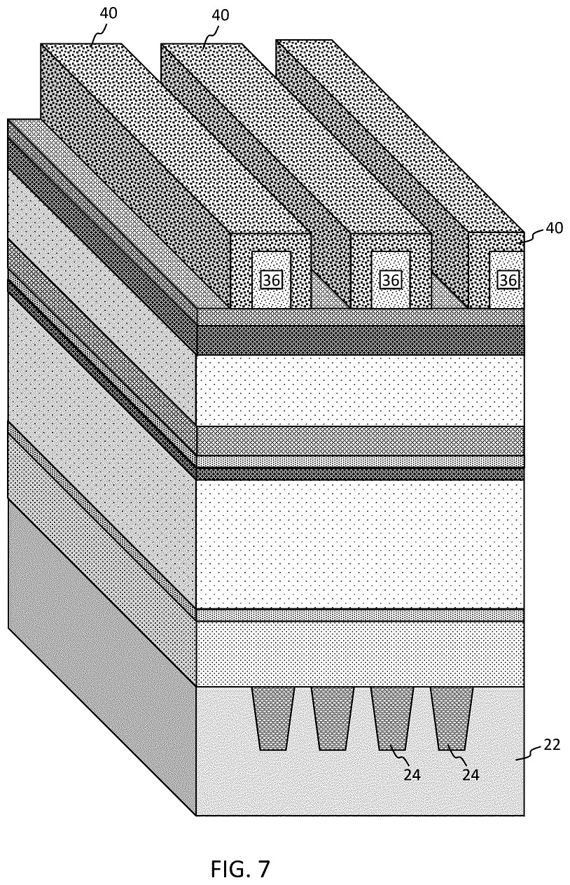

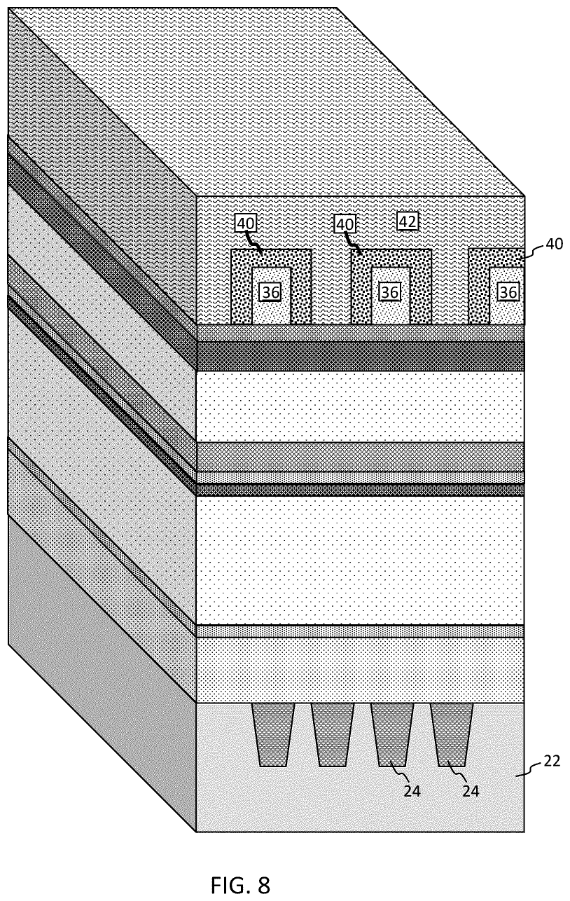

Referring to FIGS. 3C, 3H, and 7, the first overcoat layer 38 can be selectively removed while retaining most of or all of the first patterned photoresist layer 36 including most of or all of the anti-spacer regions 40.

Referring to FIGS. 3D, 3I, and 8, a second overcoat layer 42 can be deposited over the first patterned photoresist layer 36 including the anti-spacer regions 40.

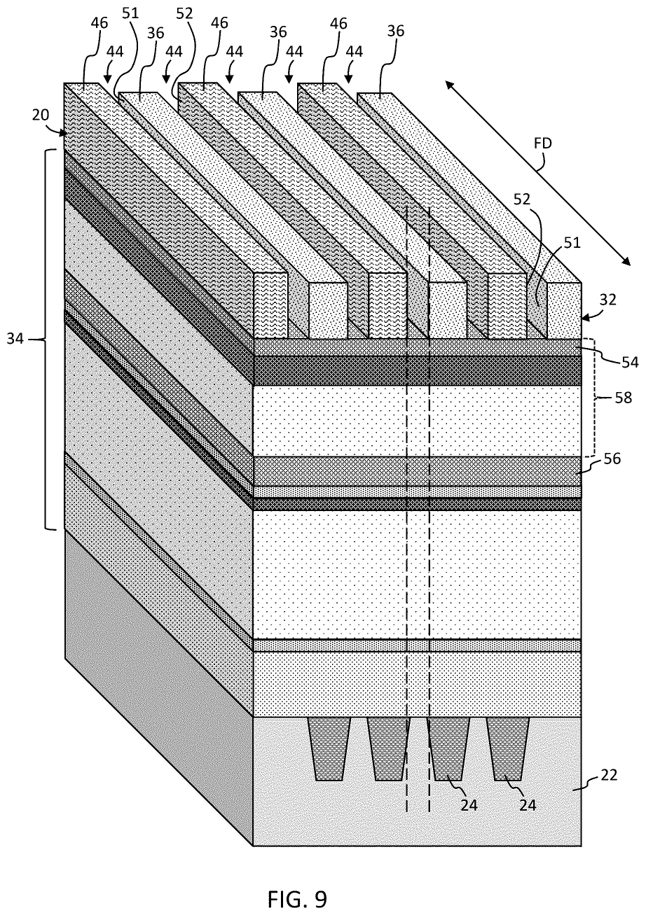

Referring to FIGS. 3E, 3J, and 9, the anti-spacer regions 40 can be selectively removed with a given developer to form the anti-spacer pattern 32 including anti-spacer trenches 44, and overburden portions and upper portions of the second overcoat layer 42 can be removed (during the selective removal of the anti-spacer regions 40) to form a patterned overcoat layer 46 from the second overcoat layer 42. Accordingly, the anti-spacer pattern 32 can be formed, and the anti-spacer pattern 32 can include the anti-spacer trenches 44 such that anti-spacer sidewalls of each of the anti-spacer trenches 44 include a first anti-spacer sidewall 51 and a second anti-spacer sidewall 52. The first anti-spacer sidewall 51 can be defined by remaining first-patterned-photoresist-layer portions of the first patterned photoresist layer 36. The second anti-spacer sidewall 52 can be defined by the patterned overcoat layer 46. The anti-spacer trenches 44 can extend along a first direction FD.

Referring to FIGS. 8 and 9, the heights of the patterned overcoat layer 46 and the remaining first-patterned-photoresist-layer portions of the first patterned photoresist layer 36 can be the same or different, based on the various etch selectivities for a given developer for the second overcoat layer 42, the anti-spacer regions 40, and the first patterned photoresist layer 36 (relative to each other). For example, the relative heights of the patterned overcoat layer 46 and the remaining first-patterned-photoresist-layer portions of the first patterned photoresist layer 36 can be different because the etch rate or etch budget of the materials of these portions can be different, and/or the etch budget for the shorter features can be sufficient for subsequent patterning. Typically, the vertical profile and/or smoothness (e.g., not tapering, not flaring, not scalloped, not rough) of the first and second anti-spacer sidewalls 51, 52 of the anti-spacer trenches 44, and/or the critical dimensions (CD) and critical dimension uniformity (CDU) of the anti-spacer trenches 44, can be much more important than whether the heights of the patterned overcoat layer 46 and the remaining first-patterned-photoresist-layer portions of the first patterned photoresist layer 36 are the same and/or consistent, and/or whether the top surface roughness and/or shape of the patterned overcoat layer 46 and the remaining first-patterned-photoresist-layer portions of the first patterned photoresist layer 36 are smooth and/or horizontally flat. However, as shown in FIG. 3J, experimental results have shown that using an embodiment of the present disclosure can provide improved CD, improved CDU, improved feature shapes, and reduced feature variations, as compared to some conventional methods (e.g., compare FIG. 1J), which can be an advantage of using an embodiment of the present disclosure.

Referring to FIG. 9, the anti-spacer trenches 44 can be vertically registered and aligned with source and drain contact locations for transistors in the substrate, in a self-aligned manner based on the initial registration/alignment operation while forming the first patterned photoresist layer 36 (see FIGS. 3A and 4). The anti-spacer pattern 32 of FIG. 9 can be equivalent in pitch, trench widths (e.g., 10-20 nm), feature sizes, or any combination thereof, as the patterned mask layer 20 of FIG. 2 (and thereby can be a patterned mask layer 20 of FIG. 2), by using an embodiment of the present disclosure. However, the pitch and feature sizes for the first patterned photoresist layer 36 of FIGS. 3A and 4, which can be used to form the anti-spacer pattern 32 of FIGS. 3E and 9, can be larger than that required using a conventional spacer process to form an equivalent patterned mask layer, as illustrated in FIG. 1A, which can be an advantage of an embodiment of the present disclosure. Also, the pitch and feature sizes for the first patterned photoresist layer 36 of FIGS. 3A and 4, which can be used to form the anti-spacer pattern 32 of FIGS. 3E and 9, can be much larger (e.g., 2×-5×) than that of the patterned mask layer 20 of FIG. 2 (thus enabling sub-lithography feature sizes), which can be an advantage of an embodiment of the present disclosure.

By starting with a first patterned photoresist layer 36 that can have relatively larger feature sizes and pitch than the resulting self-aligned anti-spacer pattern 32 (e.g., compare FIGS. 3A and 3E, and compare FIGS. 4 and 9), as well as being relatively larger feature sizes and pitch than an initial patterned photoresist layer of conventional method (e.g., compare FIGS. 1A and 3A), an embodiment of the present invention can provide improved critical dimensions (CD) and critical dimension uniformity (CDU) for a given geometry node and/or allow for progression to smaller geometry nodes, which can be advantages of using an embodiment of the present disclosure.

A comparison of the images of FIGS. 1J and 3J, in comparison to the intended or desired feature shapes and pattern of the patterned mask layer 20 in FIG. 2, shows that using an anti-spacer method according to an embodiment of the present disclosure can provide actual shapes and features much closer to the desired or ideal features shapes and pattern, which can be an advantage of an embodiment of the present disclosure. Accordingly, using an anti-spacer method according to an embodiment of the present disclosure can provide improved CD and CDU compared to conventional techniques (compare again FIGS. 1J and 3J), which can improve consistency in manufacturing by reducing device variability and thereby improving yield, which can be advantages of an embodiment of the present disclosure.

As described above and as notated in FIGS. 1A to 1E, to form the patterned spacer layer of FIGS. 1E and 1J, up to nine different tools may be required. In contrast, the anti-spacer pattern 32 of FIGS. 3E, 3J, and 9, can be formed using only two tools: a coater/developer tool and a light exposure tool. Tool notations are also provided in FIGS. 3A to 3E to clarify what tools can be used for each stage of that example process flow. The manufacturing time and cost for performing the operations for the process flow of FIGS. 1A to 1E, using the tools notated in FIGS. 1A to 1E, can be much greater compared to that of an embodiment of the present disclosure, such as the example process flow and tools notated in FIGS. 3A to 3E, which can be advantages of using an embodiment of the present disclosure. Using less tools for achieving a same, equivalent, or even better intermediate structure, can reduce costs of ownership and costs of operations for a semiconductor manufacturer, which can be advantages of using an embodiment of the present disclosure.

Referring to FIG. 9, the underlying layers 34 of the substrate 22 can include hard mask layers, such as a hard mask layers 54, 56, as well as other various layers, such as dielectric layers, etch stop layers, and barrier layers, of varying etch selectivities, for example.

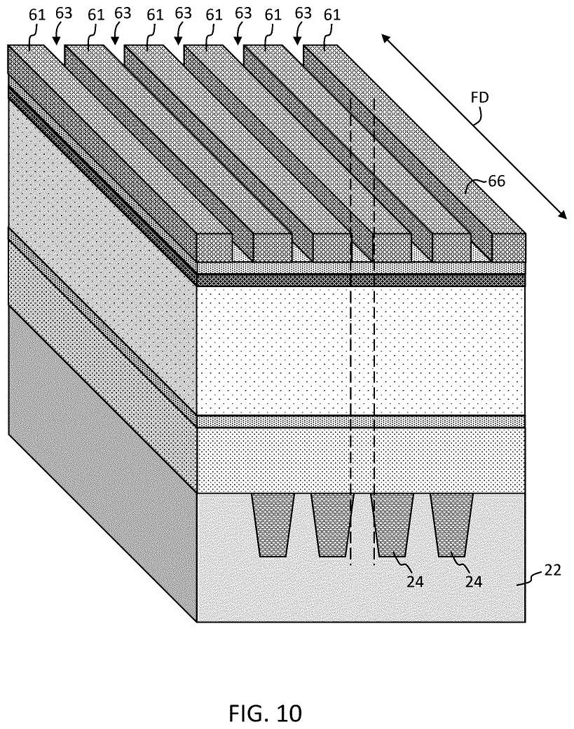

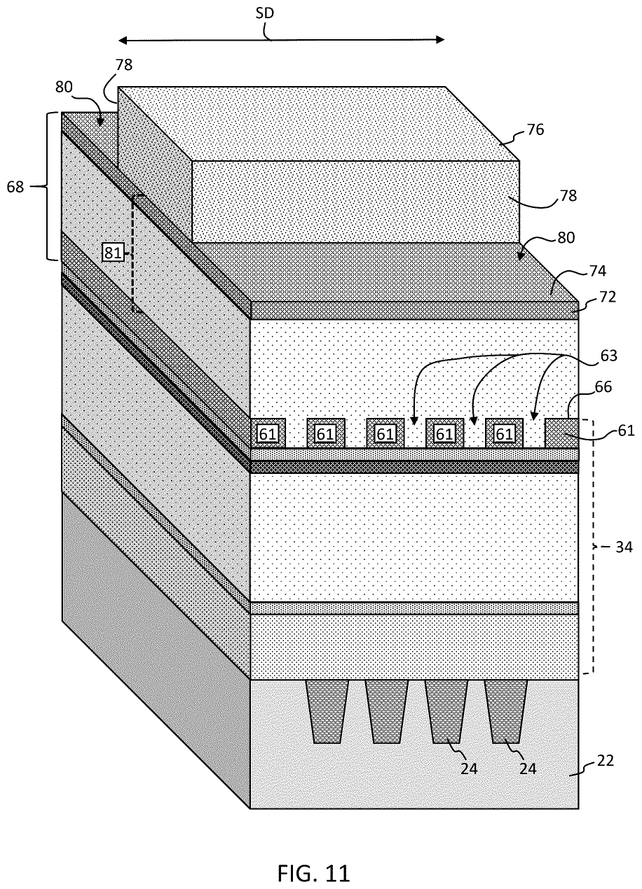

Referring to FIGS. 9 to 10, a first part 58 of the underlying layers 34 and a first hard mask layer 56 can be etched via the anti-spacer trenches 44 to transfer the anti-spacer pattern 32 into the first hard mask layer 56 to form a first patterned hard mask layer 61. The first patterned hard mask layer 61 can include first contact trenches 63 extending along the first direction FD that correspond to the anti-spacer trenches 44 (see FIG. 9), such that the first contact trenches 63 also can be vertically registered and aligned with source and drain contact locations for transistors 24 in the substrate 22.

Referring to FIG. 11, first overlying layers 68 can be formed over the first patterned hard mask layer 61. The first overlying layers 68 can include a second hard mask layer 72 at an upper portion of the first overlying layers 68. A second photoresist layer can be deposited on a first-overlying-layers top surface 74 of the first overlying layers 68, and then the second photoresist layer can be patterned using any suitable photolithography technique (e.g., DUV photolithography, immersion lithography, EUV photolithography, or high NA EUV photolithography) to form a second patterned photoresist layer 76. The second patterned photoresist layer 76 can include contact-edge features 78 and second contact trenches 80 overlapping with the first contact trenches 63 of the first patterned hard mask layer 61. The contact-edge features 78 and the second contact trenches 80 can extend in a second direction SD. The second direction SD can be non-parallel with the first direction FD. In some embodiments, the second direction SD can be perpendicular to the first direction FD, which can be typical.

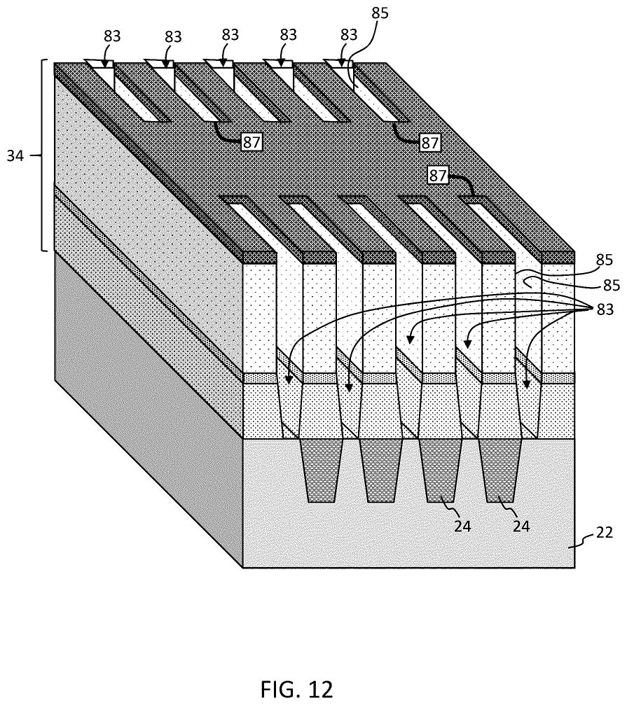

Referring to FIGS. 11 and 12, etching and patterning the second hard mask layer 72 can be performed using the second patterned photoresist layer 76 to transfer the contact-edge features 78 and the second contact trenches 80 into the second hard mask layer 72 to form a second patterned hard mask layer. Etching of the second contact trenches 80 can be continued farther into the first overlying layers 68 using the second patterned hard mask layer to expose first contact portions of the first contact trenches 63 of the first patterned hard mask layer 61 (see also FIG. 10) while a first portion 81 of the first overlying layers 68 being under and protected by the second patterned hard mask layer is not etched during the etching of the second contact trenches 80 in the first overlying layers 68, and such that the first portion 81 of the first overlying layers 68 has a first-portion top surface corresponding to a registration location of the contact-edge features 78 of the second patterned photoresist layer 76. The first-portion top surface can be vertically separated from a first-patterned-hard-mask-layer top surface 66 of the first patterned hard mask layer 61 by a first pad thickness. The second contact trenches 80 can extend in the second direction SD corresponding with the contact-edge features 78 and can overlap with the first contact trenches 63.

Referring to FIG. 12, self-aligned etching of the first contact portions in and through the first contact trenches 63 of the first patterned hard mask layer 61 (see also FIGS. 10 and 11) can be performed to extend the first contact portions into the underlying layers 34 below the first patterned hard mask layer 61 to form the third contact trenches 83. Each of the third contact trenches 83 can be defined by contact-trench sidewalls including first contact sidewalls 85 patterned by the first contact trenches 63 of the first patterned hard mask layer 61 (originally stemming from the first patterned photoresist layer 36) and second contact sidewalls 87 patterned by the second contact trenches 80 of the first overlying layers 68 (originally stemming from the second patterned photoresist layer 76). The third contact trenches 83 can open to source and drain contact locations for the transistors 24 in the substrate 22.

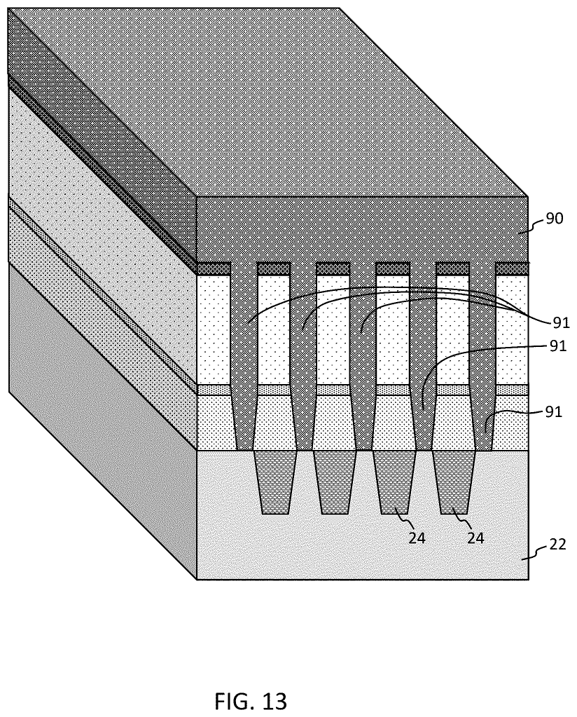

Referring to FIG. 13, conducting material and/or metal 90 can be deposited into the third contact trenches 83 to form contacts 91 at the source and drain contact locations for the transistors 24. In subsequent processing operations, the conducting material and/or metal 90 can be reduced and planarized using chemical mechanical polishing (CMP), for example, to a depth such that separated individual conductive contacts 91 are formed in the third contact trenches 83.

In an embodiment of the present disclosure, the third contact trenches 83 (see, e.g., FIG. 12) can be formed using just two photoresist masking and patterning operations. And, note that the feature size and pitch for the second patterned photoresist layer 76 (see, e.g., FIG. 11) is much larger than that of the first patterned photoresist layer 36 (see, e.g., FIG. 4). Thus, using a self-aligned process incorporating an anti-spacer pattern formation process for forming conductive contacts during manufacturing of semiconductor devices, in accordance with an embodiment of the present disclosure, a geometry node limit and/or CD limit can be based on feature size and/or pitch limits of a first patterned photoresist layer 36 (see, e.g., FIGS. 3A and 4), which can be an advantage of using an embodiment of the present disclosure.

Using an embodiment of the present disclosure, a process flow for making an anti-spacer pattern 32 and a second patterned photoresist layer 76 (overlapping in registry and alignment) can be performed using only two tools: a coater/developer tool and a light exposure tool. This can be yet another advantage of using an embodiment of the present disclosure by making further use of a given coater/developer tool, for example.

Although an example embodiment shows contacts 91 made for transistors 24, in other embodiments, contacts can be formed for any device or component, including but not necessarily limited: capacitors, diodes, memory cells, resistors, MEMs electrodes, sensor electrodes, LED/OLED elements, or any combination thereof, for example. Even though the example embodiment is a self-aligned middle-of-line (MOL) contact formation process, other self-aligned MOL and/or other FSAV process flows can use or incorporate an embodiment of the present disclosure, without necessarily departing from the spirit and scopes of the present disclosure and/or as an equivalent process within a scope of the present disclosure.

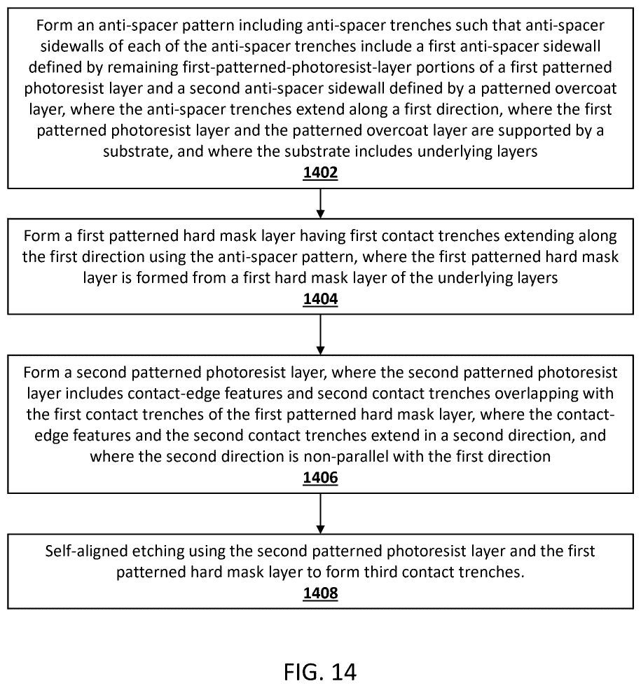

FIGS. 14 to 17B provide some example flowcharts illustrating some example methods that can be used for making the example embodiments described above and shown in FIGS. 3A to 13.

FIG. 14 is a flowchart illustrating a method for manufacturing semiconductor devices according to an embodiment of the present disclosure. In a method for manufacturing semiconductor devices, the method can include forming an anti-spacer pattern 32 including anti-spacer trenches 44 such that anti-spacer sidewalls of each of the anti-spacer trenches include a first anti-spacer sidewall 51 defined by remaining first-patterned-photoresist-layer portions of a first patterned photoresist layer 36 and a second anti-spacer sidewall 52 defined by a patterned overcoat layer 46, where the anti-spacer trenches 44 extend along a first direction FD, where the first patterned photoresist layer 36 and the patterned overcoat layer 46 are supported by a substrate 22, and where the substrate 22 includes underlying layers 34 (box 1402).

In a method for manufacturing semiconductor devices, the method can include forming a first patterned hard mask layer 61 having first contact trenches 63 extending along the first direction FD using the anti-spacer pattern 32, where the first patterned hard mask layer 61 is formed from a first hard mask layer 56 of the underlying layers 34 (box 1404). In a method for manufacturing semiconductor devices, the method can include forming a second patterned photoresist layer 76, where the second patterned photoresist layer 76 includes contact-edge features 78 and second contact trenches 80 overlapping with the first contact trenches 63 of the first patterned hard mask layer 61, where the contact-edge features 78 and the second contact trenches 80 extend in a second direction SD, and where the second direction SD is non-parallel with the first direction FD (box 1406). In a method for manufacturing semiconductor devices, the method can include self-aligned etching using the second patterned photoresist layer 76 and the first patterned hard mask layer 61 to form third contact trenches 83 (box 1408).

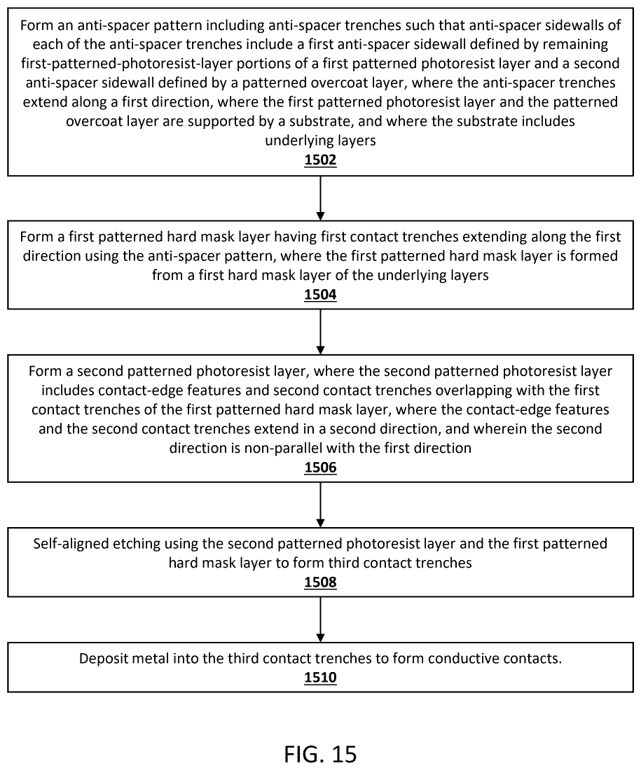

FIG. 15 is a flowchart illustrating a method for forming conductive contacts during manufacturing of semiconductor devices according to an embodiment of the present disclosure. In a method for forming conductive contacts, the method can include forming an anti-spacer pattern 32 including anti-spacer trenches 44 such that anti-spacer sidewalls of each of the anti-spacer trenches 44 include a first anti-spacer sidewall 51 defined by remaining first-patterned-photoresist-layer portions of a first patterned photoresist layer 36 and a second anti-spacer sidewall 52 defined by a patterned overcoat layer 46, where the anti-spacer trenches 44 extend along a first direction FD, where the first patterned photoresist layer 36 and the patterned overcoat layer 46 are supported by a substrate 22, and where the substrate 22 includes underlying layers 34 (box 1502).

In a method for forming conductive contacts, the method can include forming a first patterned hard mask layer 61 having first contact trenches 63 extending along the first direction FD using the anti-spacer pattern 32, where the first patterned hard mask layer 61 is formed from a first hard mask layer 56 of the underlying layers 34 (box 1504). In a method for forming conductive contacts, the method can include forming a second patterned photoresist layer 76, where the second patterned photoresist layer 76 includes contact-edge features 78 and second contact trenches 80 overlapping with the first contact trenches 63 of the first patterned hard mask layer 61, where the contact-edge features 78 and the second contact trenches 80 extend in a second direction SD, and where the second direction SD is non-parallel with the first direction FD (box 1506).

In a method for forming conductive contacts, the method can include self-aligned etching using the second patterned photoresist layer 76 and the first patterned hard mask layer 61 to form third contact trenches 83 (box 1508). In a method for forming conductive contacts, the method can include depositing metal 90 into the third contact trenches 83 to form the conductive contacts 91 (box 1510).

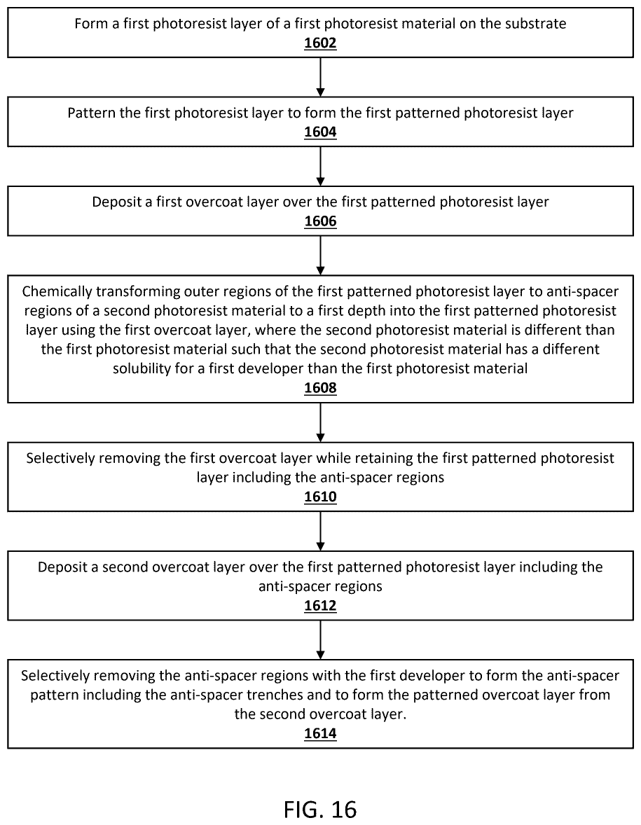

FIG. 16 is a flowchart illustrating a method for forming conductive contacts during manufacturing of semiconductor devices according to an embodiment of the present disclosure.

In a method for forming conductive contacts during manufacturing of semiconductor devices, the forming of the anti-spacer pattern 32 can include forming a first photoresist layer of a first photoresist material on the substrate 22 (box 1602). In a method for forming conductive contacts during manufacturing of semiconductor devices, the forming of the anti-spacer pattern 32 can include patterning the first photoresist layer to form the first patterned photoresist layer 36 (box 1604). In a method for forming conductive contacts during manufacturing of semiconductor devices, the forming of the anti-spacer pattern 32 can include depositing a first overcoat layer 38 over the first patterned photoresist layer 36 (box 1606).

In a method for forming conductive contacts during manufacturing of semiconductor devices, the forming of the anti-spacer pattern 32 can include chemically transforming outer regions of the first patterned photoresist layer 36 to anti-spacer regions 40 of a second photoresist material to a first depth D into the first patterned photoresist layer 36 using the first overcoat layer 38, where the second photoresist material is different than the first photoresist material such that the second photoresist material has a different solubility for a first developer than the first photoresist material, where the first depth D can be in a range of 8 nanometers to 40 nanometers (box 1608).

In a method for forming conductive contacts during manufacturing of semiconductor devices, the forming of the anti-spacer pattern 32 can include selectively removing the first overcoat layer 38 while retaining the first patterned photoresist layer 36 including the anti-spacer regions 40 (box 1610). In a method for forming conductive contacts during manufacturing of semiconductor devices, the forming of the anti-spacer pattern 32 can include depositing a second overcoat layer 42 over the first patterned photoresist layer 36 including the anti-spacer regions 40 (box 1612). In a method for forming conductive contacts during manufacturing of semiconductor devices, the forming of the anti-spacer pattern 32 can include selectively removing the anti-spacer regions 40 with the first developer to form the anti-spacer pattern 32 including the anti-spacer trenches 44 and to form the patterned overcoat layer 46 from the second overcoat layer 42 (box 1614).

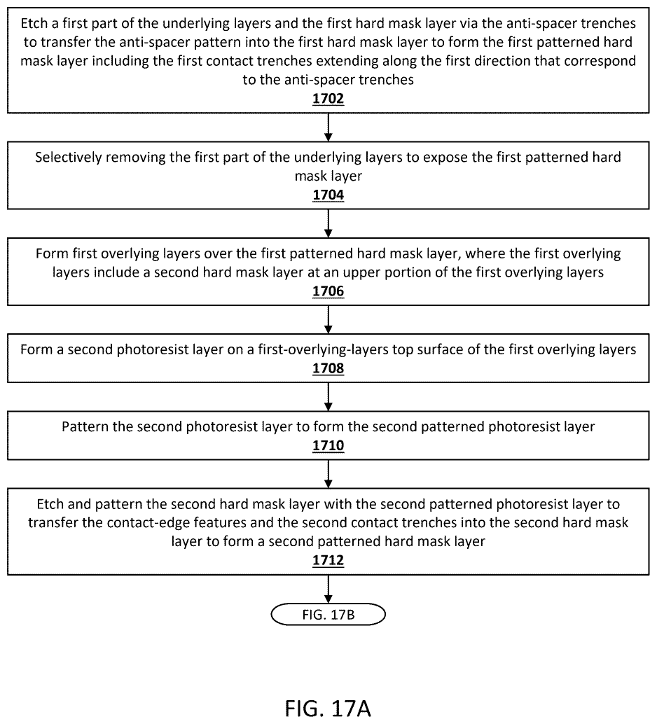

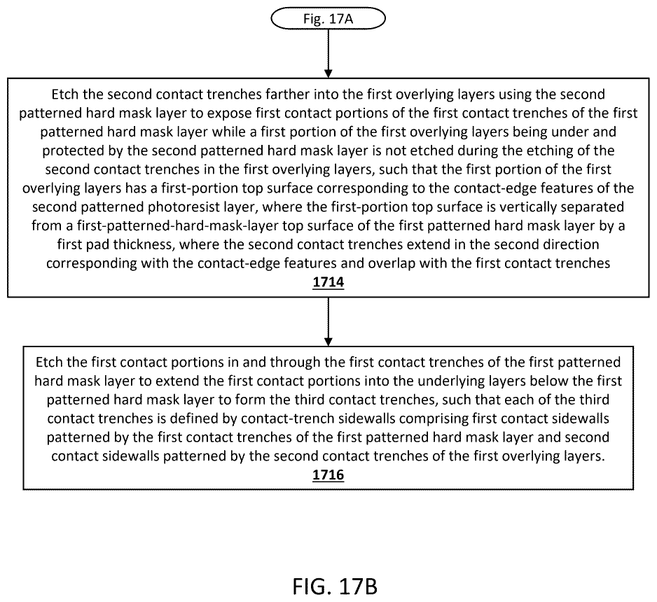

FIGS. 17A and 17B is a flowchart illustrating a method for forming conductive contacts during manufacturing of semiconductor devices according to an embodiment of the present disclosure. In a method for forming conductive contacts during manufacturing of semiconductor devices, the underlying layers 34 can include a first hard mask layer 56, and the forming of the first patterned hard mask layer 61 can include etching a first part 58 of the underlying layers 34 and the first hard mask layer 56 via the anti-spacer trenches 44 to transfer the anti-spacer pattern 32 into the first hard mask layer 56 to form the first patterned hard mask layer 61 including first contact trenches 63 extending along the first direction FD that correspond to the anti-spacer trenches 44 (box 1702).

In a method for forming conductive contacts during manufacturing of semiconductor devices, the forming of the second patterned photoresist layer 76 and the self-aligned etching can include selectively removing the first part 58 of the underlying layers 34 to expose the first patterned hard mask layer 61 (box 1704). In a method for forming conductive contacts during manufacturing of semiconductor devices, the forming of the second patterned photoresist layer 76 and the self-aligned etching can include forming first overlying layers 68 over the first patterned hard mask layer 61, where the first overlying layers 68 include a second hard mask layer 72 at an upper portion of the first overlying layers 68 (box 1706).

In a method for forming conductive contacts during manufacturing of semiconductor devices, the forming of the second patterned photoresist layer 76 and the self-aligned etching can include forming a second photoresist layer on a first-overlying-layers top surface 74 of the first overlying layers 68 (box 1708). In a method for forming conductive contacts during manufacturing of semiconductor devices, the forming of the second patterned photoresist layer 76 and the self-aligned etching can include patterning the second photoresist layer to form the second patterned photoresist layer 76 (box 1710).

In a method for forming conductive contacts during manufacturing of semiconductor devices, the forming of the second patterned photoresist layer 76 and the self-aligned etching can include etching and patterning the second hard mask layer 72 with the second patterned photoresist layer 76 to transfer the contact-edge features 78 and the second contact trenches 80 into the second hard mask layer 72 to form a second patterned hard mask layer (box 1712).

In a method for forming conductive contacts during manufacturing of semiconductor devices, the forming of the second patterned photoresist layer 76 and the self-aligned etching can include etching the second contact trenches 80 farther into the first overlying layers 68 using the second patterned hard mask layer to expose first contact portions of the first contact trenches 63 of the first patterned hard mask layer 61 while a first portion 81 of the first overlying layers 68 being under and protected by the second patterned hard mask layer is not etched during the etching of the second contact trenches 80 in the first overlying layers 68, such that the first portion 81 of the first overlying layers 68 has a first-portion top surface corresponding to the contact-edge features 78 of the second patterned photoresist layer 76, where the first-portion top surface is vertically separated from a first-patterned-hard-mask-layer top surface 66 of the first patterned hard mask layer 61 by a first pad thickness PT, where the second contact trenches 80 extend in the second direction SD corresponding with the contact-edge features 78 and overlap with the first contact trenches 63 (box 1714).

In a method for forming conductive contacts during manufacturing of semiconductor devices, the forming of the second patterned photoresist layer 76 and the self-aligned etching can include etching the first contact portions in and through the first contact trenches 63 of the first patterned hard mask layer 61 to extend the first contact portions into the underlying layers 34 below the first patterned hard mask layer 61 to form the third contact trenches 83, such that each of the third contact trenches 83 is defined by contact-trench sidewalls including first contact sidewalls 85 patterned by the first contact trenches 63 of the first patterned hard mask layer 61 and second contact sidewalls 87 patterned by the second contact trenches 80 of the first overlying layers 68 (box 1716).

More example embodiments of the present disclosure are summarized here. Other embodiments can also be understood from the entirety of the specification as well as the claims filed herein.

Example 1. A method for manufacturing semiconductor devices, the method including: forming an anti-spacer pattern including anti-spacer trenches such that anti-spacer sidewalls of each of the anti-spacer trenches include a first anti-spacer sidewall defined by remaining first-patterned-photoresist-layer portions of a first patterned photoresist layer and a second anti-spacer sidewall defined by a patterned overcoat layer, where the anti-spacer trenches extend along a first direction, where the first patterned photoresist layer and the patterned overcoat layer are supported by a substrate, and where the substrate includes underlying layers; forming a first patterned hard mask layer having first contact trenches extending along the first direction using the anti-spacer pattern, where the first patterned hard mask layer is formed from a first hard mask layer of the underlying layers; forming a second patterned photoresist layer, where the second patterned photoresist layer includes contact-edge features and second contact trenches overlapping with the first contact trenches of the first patterned hard mask layer, where the contact-edge features and the second contact trenches extend in a second direction, and where the second direction is non-parallel with the first direction; and self-aligned etching using the second patterned photoresist layer and the first patterned hard mask layer to form third contact trenches.

Example 2. The method of example 1, where the forming of the anti-spacer pattern and the forming of the second patterned photoresist layer are performed using only two tools, where the two tools include a coater/developer tool and a light exposure tool.

Example 3. The method of one of examples 1 or 2, where the anti-spacer pattern is vertically aligned with source and drain contact locations for transistors in the substrate, and where the method further includes depositing metal into the third contact trenches to form contacts at the source and drain contact locations for the transistors.

Example 4. The method of one of examples 1 to 3, where the forming of the anti-spacer pattern includes: forming a first photoresist layer of a first photoresist material on the substrate; patterning the first photoresist layer to form the first patterned photoresist layer; depositing a first overcoat layer over the first patterned photoresist layer; chemically transforming outer regions of the first patterned photoresist layer to anti-spacer regions of a second photoresist material to a first depth into the first patterned photoresist layer using the first overcoat layer, where the second photoresist material is different than the first photoresist material such that the second photoresist material has a different solubility for a first developer than the first photoresist material; selectively removing the first overcoat layer while retaining the first patterned photoresist layer including the anti-spacer regions; depositing a second overcoat layer over the first patterned photoresist layer including the anti-spacer regions; and selectively removing the anti-spacer regions with the first developer to form the anti-spacer pattern including the anti-spacer trenches and to form the patterned overcoat layer from the second overcoat layer.

Example 5. The method of one of examples 1 to 4, where the forming of the anti-spacer pattern is performed using only two tools, where the two tools include a coater/developer tool and a light exposure tool.

Example 6. The method of one of examples 1 to 5, where the first depth is in a range of 10 nanometers to 20 nanometers.

Example 7. The method of one of examples 1 to 6, where the chemically transforming of the outer regions of the first patterned photoresist layer includes diffusing acid from the first overcoat layer into the outer regions of the first patterned photoresist layer to increase solubility of the outer regions for the first developer such that the outer regions become the anti-spacer regions.

Example 8. The method of one of examples 1 to 7, where the underlying layers include the first hard mask layer, and where the forming of the first patterned hard mask layer includes etching a first part of the underlying layers and the first hard mask layer via the anti-spacer trenches to transfer the anti-spacer pattern into the first hard mask layer to form the first patterned hard mask layer including the first contact trenches extending along the first direction that correspond to the anti-spacer trenches.

Example 9. The method of one of examples 1 to 8, where the forming of the second patterned photoresist layer and the self-aligned etching include: selectively removing the first part of the underlying layers to expose the first patterned hard mask layer; forming first overlying layers over the first patterned hard mask layer, where the first overlying layers include a second hard mask layer at an upper portion of the first overlying layers; forming a second photoresist layer on a first-overlying-layers top surface of the first overlying layers; patterning the second photoresist layer to form the second patterned photoresist layer; etching and patterning the second hard mask layer with the second patterned photoresist layer to transfer the contact-edge features and the second contact trenches into the second hard mask layer to form a second patterned hard mask layer; etching the second contact trenches farther into the first overlying layers using the second patterned hard mask layer to expose first contact portions of the first contact trenches of the first patterned hard mask layer while a first portion of the first overlying layers being under and protected by the second patterned hard mask layer is not etched during the etching of the second contact trenches in the first overlying layers, such that the first portion of the first overlying layers has a first-portion top surface corresponding to the contact-edge features of the second patterned photoresist layer, where the first-portion top surface is vertically separated from a first-patterned-hard-mask-layer top surface of the first patterned hard mask layer by a first pad thickness, where the second contact trenches extend in the second direction corresponding with the contact-edge features and overlap with the first contact trenches; and etching the first contact portions in and through the first contact trenches of the first patterned hard mask layer to extend the first contact portions into the underlying layers below the first patterned hard mask layer to form the third contact trenches, such that each of the third contact trenches is defined by contact-trench sidewalls including first contact sidewalls patterned by the first contact trenches of the first patterned hard mask layer and second contact sidewalls patterned by the second contact trenches of the first overlying layers.

Example 10. The method of one of examples 1 to 9, where the forming of the anti-spacer pattern and the forming of the second patterned photoresist layer are performed using only two tools, where the two tools include a coater/developer tool and a light exposure tool.

Example 11. A method for forming conductive contacts during manufacturing of semiconductor devices, the method including: forming an anti-spacer pattern including anti-spacer trenches such that anti-spacer sidewalls of each of the anti-spacer trenches include a first anti-spacer sidewall defined by remaining first-patterned-photoresist-layer portions of a first patterned photoresist layer and a second anti-spacer sidewall defined by a patterned overcoat layer, where the anti-spacer trenches extend along a first direction, where the first patterned photoresist layer and the patterned overcoat layer are supported by a substrate, and where the substrate includes underlying layers; forming a first patterned hard mask layer having first contact trenches extending along the first direction using the anti-spacer pattern, where the first patterned hard mask layer is formed from a first hard mask layer of the underlying layers; forming a second patterned photoresist layer, where the second patterned photoresist layer includes contact-edge features and second contact trenches overlapping with the first contact trenches of the first patterned hard mask layer, where the contact-edge features and the second contact trenches extend in a second direction, and where the second direction is non-parallel with the first direction; self-aligned etching using the second patterned photoresist layer and the first patterned hard mask layer to form third contact trenches; and depositing metal into the third contact trenches to form the conductive contacts.

Example 12. The method of example 11, where the forming of the anti-spacer pattern and the forming of the second patterned photoresist layer are performed using only two tools, where the two tools include a coater/developer tool and a light exposure tool.

Example 13. The method of one of examples 11 or 12, where the forming of the anti-spacer pattern includes: forming a first photoresist layer of a first photoresist material on the substrate; patterning the first photoresist layer to form the first patterned photoresist layer; depositing a first overcoat layer over the first patterned photoresist layer; chemically transforming outer regions of the first patterned photoresist layer to anti-spacer regions of a second photoresist material to a first depth into the first patterned photoresist layer using the first overcoat layer, where the second photoresist material is different than the first photoresist material such that the second photoresist material has a different solubility for a first developer than the first photoresist material, where the first depth is in a range of 8 nanometers to 40 nanometers; selectively removing the first overcoat layer while retaining the first patterned photoresist layer including the anti-spacer regions; depositing a second overcoat layer over the first patterned photoresist layer including the anti-spacer regions; and selectively removing the anti-spacer regions with the first developer to form the anti-spacer pattern including the anti-spacer trenches and to form the patterned overcoat layer from the second overcoat layer.

Example 14. The method of one of examples 11 to 13, where the chemically transforming of the outer regions of the first patterned photoresist layer includes diffusing acid from the first overcoat layer into the outer regions of the first patterned photoresist layer to increase solubility of the outer regions for the first developer such that the outer regions become the anti-spacer regions.

Example 15. The method of one of examples 11 to 14, where the underlying layers include the first hard mask layer, and where the forming of the first patterned hard mask layer includes etching a first part of the underlying layers and the first hard mask layer via the anti-spacer trenches to transfer the anti-spacer pattern into the first hard mask layer to form the first patterned hard mask layer including the first contact trenches extending along the first direction that correspond to the anti-spacer trenches.

Example 16. The method of one of examples 11 to 15, where the forming of the second patterned photoresist layer and the self-aligned etching include: selectively removing the first part of the underlying layers to expose the first patterned hard mask layer; forming first overlying layers over the first patterned hard mask layer, where the first overlying layers include a second hard mask layer at an upper portion of the first overlying layers; forming a second photoresist layer on a first-overlying-layers top surface of the first overlying layers; patterning the second photoresist layer to form the second patterned photoresist layer; etching and patterning the second hard mask layer with the second patterned photoresist layer to transfer the contact-edge features and the second contact trenches into the second hard mask layer to form a second patterned hard mask layer; etching the second contact trenches farther into the first overlying layers using the second patterned hard mask layer to expose first contact portions of the first contact trenches of the first patterned hard mask layer while a first portion of the first overlying layers being under and protected by the second patterned hard mask layer is not etched during the etching of the second contact trenches in the first overlying layers, such that the first portion of the first overlying layers has a first-portion top surface corresponding to the contact-edge features of the second patterned photoresist layer, where the first-portion top surface is vertically separated from a first-patterned-hard-mask-layer top surface of the first patterned hard mask layer by a first pad thickness, where the second contact trenches extend in the second direction corresponding with the contact-edge features and overlap with the first contact trenches; and etching the first contact portions in and through the first contact trenches of the first patterned hard mask layer to extend the first contact portions into the underlying layers below the first patterned hard mask layer to form the third contact trenches, such that each of the third contact trenches is defined by contact-trench sidewalls including first contact sidewalls patterned by the first contact trenches of the first patterned hard mask layer and second contact sidewalls patterned by the second contact trenches of the first overlying layers.

Example 17. A semiconductor device including conductive contacts formed using a method including: forming an anti-spacer pattern including anti-spacer trenches such that anti-spacer sidewalls of each of the anti-spacer trenches include a first anti-spacer sidewall defined by remaining first-patterned-photoresist-layer portions of a first patterned photoresist layer and a second anti-spacer sidewall defined by a patterned overcoat layer, where the anti-spacer trenches extend along a first direction, where the first patterned photoresist layer and the patterned overcoat layer are supported by a substrate, and where the substrate includes underlying layers; forming a first patterned hard mask layer having first contact trenches extending along the first direction using the anti-spacer pattern, where the first patterned hard mask layer is formed from a first hard mask layer of the underlying layers; forming a second patterned photoresist layer, where the second patterned photoresist layer includes contact-edge features and second contact trenches overlapping with the first contact trenches of the first patterned hard mask layer, where the contact-edge features and the second contact trenches extend in a second direction, and where the second direction is non-parallel with the first direction; self-aligned etching using the second patterned photoresist layer and the first patterned hard mask layer to form third contact trenches; and depositing metal into the third contact trenches to form the conductive contacts.

Example 18. The device of example 17, where the forming of the anti-spacer pattern and the forming of the second patterned photoresist layer are performed using only two tools, where the two tools include a coater/developer tool and a light exposure tool.

Example 19. The device of one of examples 17 or 18, where the forming of the anti-spacer pattern includes: forming a first photoresist layer of a first photoresist material on the substrate; patterning the first photoresist layer to form the first patterned photoresist layer; depositing a first overcoat layer over the first patterned photoresist layer; chemically transforming outer regions of the first patterned photoresist layer to anti-spacer regions of a second photoresist material to a first depth into the first patterned photoresist layer using the first overcoat layer, where the second photoresist material is different than the first photoresist material such that the second photoresist material has a different solubility for a first developer than the first photoresist material; selectively removing the first overcoat layer while retaining the first patterned photoresist layer including the anti-spacer regions; depositing a second overcoat layer over the first patterned photoresist layer including the anti-spacer regions; and selectively removing the anti-spacer regions with the first developer to form the anti-spacer pattern including the anti-spacer trenches and to form the patterned overcoat layer from the second overcoat layer.

Example 20. The device of one of examples 17 to 19, where the underlying layers include the first hard mask layer, and where the forming of the first patterned hard mask layer includes etching a first part of the underlying layers and the first hard mask layer via the anti-spacer trenches to transfer the anti-spacer pattern into the first hard mask layer to form the first patterned hard mask layer including the first contact trenches extending along the first direction that correspond to the anti-spacer trenches, and where the forming of the second patterned photoresist layer and the self-aligned etching include: selectively removing the first part of the underlying layers to expose the first patterned hard mask layer; forming first overlying layers over the first patterned hard mask layer, where the first overlying layers include a second hard mask layer at an upper portion of the first overlying layers; forming a second photoresist layer on a first-overlying-layers top surface of the first overlying layers; patterning the second photoresist layer to form the second patterned photoresist layer; etching and patterning the second hard mask layer with the second patterned photoresist layer to transfer the contact-edge features and the second contact trenches into the second hard mask layer to form a second patterned hard mask layer; etching the second contact trenches farther into the first overlying layers using the second patterned hard mask layer to expose first contact portions of the first contact trenches of the first patterned hard mask layer while a first portion of the first overlying layers being under and protected by the second patterned hard mask layer is not etched during the etching of the second contact trenches in the first overlying layers, such that the first portion of the first overlying layers has a first-portion top surface corresponding to the contact-edge features of the second patterned photoresist layer, where the first-portion top surface is vertically separated from a first-patterned-hard-mask-layer top surface of the first patterned hard mask layer by a first pad thickness, where the second contact trenches extend in the second direction corresponding with the contact-edge features and overlap with the first contact trenches; and etching the first contact portions in and through the first contact trenches of the first patterned hard mask layer to extend the first contact portions into the underlying layers below the first patterned hard mask layer to form the third contact trenches, such that each of the third contact trenches is defined by contact-trench sidewalls including first contact sidewalls patterned by the first contact trenches of the first patterned hard mask layer and second contact sidewalls patterned by the second contact trenches of the first overlying layers.

While illustrative and example embodiments have been described with reference to illustrative drawings, this description is not intended to be construed in a necessarily limiting sense. Various modifications and combinations of the illustrative and example embodiments, as well as other embodiments, can be apparent to persons skilled in the pertinent art upon referencing the present disclosure. It is therefore intended that the appended claims encompass any and all of such modifications, equivalents, or embodiments.

What is claimed is:

1. A method for manufacturing semiconductor devices, the method comprising:
forming an anti-spacer pattern comprising anti-spacer trenches such that anti-spacer sidewalls of each of the anti-spacer trenches comprise a first anti-spacer sidewall defined by remaining first-patterned-photoresist-layer portions of a first patterned photoresist layer and a second anti-spacer sidewall defined by a patterned overcoat layer, wherein the anti-spacer trenches extend along a first direction, wherein the first patterned photoresist layer and the patterned overcoat layer are supported by a substrate, and wherein the substrate comprises underlying layers;
forming a first patterned hard mask layer having first contact trenches extending along the first direction using the anti-spacer pattern, wherein the first patterned hard mask layer is formed from a first hard mask layer of the underlying layers;
forming a second patterned photoresist layer, wherein the second patterned photoresist layer comprises contact-edge features and second contact trenches overlapping with the first contact trenches of the first patterned hard mask layer, wherein the contact-edge features and the second contact trenches extend in a second direction, and wherein the second direction is non-parallel with the first direction; and
self-aligned etching using the second patterned photoresist layer and the first patterned hard mask layer to form third contact trenches.

2. The method of claim 1, wherein the forming of the anti-spacer pattern and the forming of the second patterned photoresist layer are performed using only two tools, wherein the two tools comprise a coater/developer tool and a light exposure tool.

3. The method of claim 1, wherein the anti-spacer pattern is vertically aligned with source and drain contact locations for transistors in the substrate, and wherein the method further comprises depositing metal into the third contact trenches to form contacts at the source and drain contact locations for the transistors.

4. The method of claim 1, wherein the forming of the anti-spacer pattern comprises:
forming a first photoresist layer of a first photoresist material on the substrate;
patterning the first photoresist layer to form the first patterned photoresist layer;
depositing a first overcoat layer over the first patterned photoresist layer;
chemically transforming outer regions of the first patterned photoresist layer to anti-spacer regions of a second photoresist material to a first depth into the first patterned photoresist layer using the first overcoat layer, wherein the second photoresist material is different than the first photoresist material such that the second photoresist material has a different solubility for a first developer than the first photoresist material;
selectively removing the first overcoat layer while retaining the first patterned photoresist layer including the anti-spacer regions;
depositing a second overcoat layer over the first patterned photoresist layer including the anti-spacer regions; and
selectively removing the anti-spacer regions with the first developer to form the anti-spacer pattern comprising the anti-spacer trenches and to form the patterned overcoat layer from the second overcoat layer.

5. The method of claim 4, wherein the forming of the anti-spacer pattern is performed using only two tools, wherein the two tools comprise a coater/developer tool and a light exposure tool.

6. The method of claim 4, wherein the first depth is in a range of 10 nanometers to 20 nanometers.

7. The method of claim 4, wherein the chemically transforming of the outer regions of the first patterned photoresist layer comprises diffusing acid from the first overcoat layer into the outer regions of the first patterned photoresist layer to increase solubility of the outer regions for the first developer such that the outer regions become the anti-spacer regions.

8. The method of claim 4, wherein the underlying layers include the first hard mask layer, and wherein the forming of the first patterned hard mask layer comprises etching a first part of the underlying layers and the first hard mask layer via the anti-spacer trenches to transfer the anti-spacer pattern into the first hard mask layer to form the first patterned hard mask layer comprising the first contact trenches extending along the first direction that correspond to the anti-spacer trenches.

9. The method of claim 8, wherein the forming of the second patterned photoresist layer and the self-aligned etching comprise:
selectively removing the first part of the underlying layers to expose the first patterned hard mask layer;
forming first overlying layers over the first patterned hard mask layer, wherein the first overlying layers comprise a second hard mask layer at an upper portion of the first overlying layers;
forming a second photoresist layer on a first-overlying-layers top surface of the first overlying layers;
patterning the second photoresist layer to form the second patterned photoresist layer;
etching and patterning the second hard mask layer with the second patterned photoresist layer to transfer the contact-edge features and the second contact trenches into the second hard mask layer to form a second patterned hard mask layer;
etching the second contact trenches farther into the first overlying layers using the second patterned hard mask layer to expose first contact portions of the first contact trenches of the first patterned hard mask layer while a first portion of the first overlying layers being under and protected by the second patterned hard mask layer is not etched during the etching of the second contact trenches in the first overlying layers, such that the first portion of the first overlying layers has a first-portion top surface corresponding to the contact-edge features of the second patterned photoresist layer, wherein the first-portion top surface is vertically separated from a first-patterned-hard-mask-layer top surface of the first patterned hard mask layer by a first pad thickness, wherein the second contact trenches extend in the second direction corresponding with the contact-edge features and overlap with the first contact trenches; and
etching the first contact portions in and through the first contact trenches of the first patterned hard mask layer to extend the first contact portions into the underlying layers below the first patterned hard mask layer to form the third contact trenches, such that each of the third contact trenches is defined by contact-trench sidewalls comprising first contact sidewalls patterned by the first contact trenches of the first patterned hard mask layer and second contact sidewalls patterned by the second contact trenches of the first overlying layers.

10. The method of claim 9, wherein the forming of the anti-spacer pattern and the forming of the second patterned photoresist layer are performed using only two tools, wherein the two tools comprise a coater/developer tool and a light exposure tool.

11. A method for forming conductive contacts during manufacturing of semiconductor devices, the method comprising:
forming an anti-spacer pattern comprising anti-spacer trenches such that anti-spacer sidewalls of each of the anti-spacer trenches comprise a first anti-spacer sidewall defined by remaining first-patterned-photoresist-layer portions of a first patterned photoresist layer and a second anti-spacer sidewall defined by a patterned overcoat layer, wherein the anti-spacer trenches extend along a first direction, wherein the first patterned photoresist layer and the patterned overcoat layer are supported by a substrate, and wherein the substrate comprises underlying layers;
forming a first patterned hard mask layer having first contact trenches extending along the first direction using the anti-spacer pattern, wherein the first patterned hard mask layer is formed from a first hard mask layer of the underlying layers;
forming a second patterned photoresist layer, wherein the second patterned photoresist layer comprises contact-edge features and second contact trenches overlapping with the first contact trenches of the first patterned hard mask layer, wherein the contact-edge features and the second contact trenches extend in a second direction, and wherein the second direction is non-parallel with the first direction;
self-aligned etching using the second patterned photoresist layer and the first patterned hard mask layer to form third contact trenches; and
depositing metal into the third contact trenches to form the conductive contacts.

12. The method of claim 11, wherein the forming of the anti-spacer pattern and the forming of the second patterned photoresist layer are performed using only two tools, wherein the two tools comprise a coater/developer tool and a light exposure tool.

13. The method of claim 11, wherein the forming of the anti-spacer pattern comprises:
forming a first photoresist layer of a first photoresist material on the substrate;
patterning the first photoresist layer to form the first patterned photoresist layer;
depositing a first overcoat layer over the first patterned photoresist layer;
chemically transforming outer regions of the first patterned photoresist layer to anti-spacer regions of a second photoresist material to a first depth into the first patterned photoresist layer using the first overcoat layer, wherein the second photoresist material is different than the first photoresist material such that the second photoresist material has a different solubility for a first developer than the first photoresist material, wherein the first depth is in a range of 8 nanometers to 40 nanometers;
selectively removing the first overcoat layer while retaining the first patterned photoresist layer including the anti-spacer regions;
depositing a second overcoat layer over the first patterned photoresist layer including the anti-spacer regions; and
selectively removing the anti-spacer regions with the first developer to form the anti-spacer pattern comprising the anti-spacer trenches and to form the patterned overcoat layer from the second overcoat layer.

14. The method of claim 13, wherein the chemically transforming of the outer regions of the first patterned photoresist layer comprises diffusing acid from the first overcoat layer into the outer regions of the first patterned photoresist layer to increase solubility of the outer regions for the first developer such that the outer regions become the anti-spacer regions.

15. The method of claim 13, wherein the underlying layers include the first hard mask layer, and wherein the forming of the first patterned hard mask layer comprises etching a first part of the underlying layers and the first hard mask layer via the anti-spacer trenches to transfer the anti-spacer pattern into the first hard mask layer to form the first patterned hard mask layer comprising the first contact trenches extending along the first direction that correspond to the anti-spacer trenches.

16. The method of claim 15, wherein the forming of the second patterned photoresist layer and the self-aligned etching comprise:
selectively removing the first part of the underlying layers to expose the first patterned hard mask layer;
forming first overlying layers over the first patterned hard mask layer, wherein the first overlying layers comprise a second hard mask layer at an upper portion of the first overlying layers;
forming a second photoresist layer on a first-overlying-layers top surface of the first overlying layers;
patterning the second photoresist layer to form the second patterned photoresist layer;
etching and patterning the second hard mask layer with the second patterned photoresist layer to transfer the contact-edge features and the second contact trenches into the second hard mask layer to form a second patterned hard mask layer;
etching the second contact trenches farther into the first overlying layers using the second patterned hard mask layer to expose first contact portions of the first contact trenches of the first patterned hard mask layer while a first portion of the first overlying layers being under and protected by the second patterned hard mask layer is not etched during the etching of the second contact trenches in the first overlying layers, such that the first portion of the first overlying layers has a first-portion top surface corresponding to the contact-edge features of the second patterned photoresist layer, wherein the first-portion top surface is vertically separated from a first-patterned-hard-mask-layer top surface of the first patterned hard mask layer by a first pad thickness, wherein the second contact trenches extend in the second direction corresponding with the contact-edge features and overlap with the first contact trenches; and
etching the first contact portions in and through the first contact trenches of the first patterned hard mask layer to extend the first contact portions into the underlying layers below the first patterned hard mask layer to form the third contact trenches, such that each of the third contact trenches is defined by contact-trench sidewalls comprising first contact sidewalls patterned by the first contact trenches of the first patterned hard mask layer and second contact sidewalls patterned by the second contact trenches of the first overlying layers.

17. A semiconductor device comprising conductive contacts formed using a method comprising:
forming an anti-spacer pattern comprising anti-spacer trenches such that anti-spacer sidewalls of each of the anti-spacer trenches comprise a first anti-spacer sidewall defined by remaining first-patterned-photoresist-layer portions of a first patterned photoresist layer and a second anti-spacer sidewall defined by a patterned overcoat layer, wherein the anti-spacer trenches extend along a first direction, wherein the first patterned photoresist layer and the patterned overcoat layer are supported by a substrate, and wherein the substrate comprises underlying layers;
forming a first patterned hard mask layer having first contact trenches extending along the first direction using the anti-spacer pattern, wherein the first patterned hard mask layer is formed from a first hard mask layer of the underlying layers;
forming a second patterned photoresist layer, wherein the second patterned photoresist layer comprises contact-edge features and second contact trenches overlapping with the first contact trenches of the first patterned hard mask layer, wherein the contact-edge features and the second contact trenches extend in a second direction, and wherein the second direction is non-parallel with the first direction;
self-aligned etching using the second patterned photoresist layer and the first patterned hard mask layer to form third contact trenches; and
depositing metal into the third contact trenches to form the conductive contacts.

18. The device of claim 17, wherein the forming of the anti-spacer pattern and the forming of the second patterned photoresist layer are performed using only two tools, wherein the two tools comprise a coater/developer tool and a light exposure tool.

19. The device of claim 17, wherein the forming of the anti-spacer pattern comprises:
forming a first photoresist layer of a first photoresist material on the substrate;
patterning the first photoresist layer to form the first patterned photoresist layer;
depositing a first overcoat layer over the first patterned photoresist layer;
chemically transforming outer regions of the first patterned photoresist layer to anti-spacer regions of a second photoresist material to a first depth into the first patterned photoresist layer using the first overcoat layer, wherein the second photoresist material is different than the first photoresist material such that the second photoresist material has a different solubility for a first developer than the first photoresist material;
selectively removing the first overcoat layer while retaining the first patterned photoresist layer including the anti-spacer regions;
depositing a second overcoat layer over the first patterned photoresist layer including the anti-spacer regions; and
selectively removing the anti-spacer regions with the first developer to form the anti-spacer pattern comprising the anti-spacer trenches and to form the patterned overcoat layer from the second overcoat layer.

20. The device of claim 19, wherein the underlying layers include the first hard mask layer, and wherein the forming of the first patterned hard mask layer comprises etching a first part of the underlying layers and the first hard mask layer via the anti-spacer trenches to transfer the anti-spacer pattern into the first hard mask layer to form the first patterned hard mask layer comprising the first contact trenches extending along the first direction that correspond to the anti-spacer trenches, and
wherein the forming of the second patterned photoresist layer and the self-aligned etching comprise:
selectively removing the first part of the underlying layers to expose the first patterned hard mask layer;
forming first overlying layers over the first patterned hard mask layer, wherein the first overlying layers comprise a second hard mask layer at an upper portion of the first overlying layers;
forming a second photoresist layer on a first-overlying-layers top surface of the first overlying layers;
patterning the second photoresist layer to form the second patterned photoresist layer;
etching and patterning the second hard mask layer with the second patterned photoresist layer to transfer the contact-edge features and the second contact trenches into the second hard mask layer to form a second patterned hard mask layer;
etching the second contact trenches farther into the first overlying layers using the second patterned hard mask layer to expose first contact portions of the first contact trenches of the first patterned hard mask layer while a first portion of the first overlying layers being under and protected by the second patterned hard mask layer is not etched during the etching of the second contact trenches in the first overlying layers, such that the first portion of the first overlying layers has a first-portion top surface corresponding to the contact-edge features of the second patterned photoresist layer, wherein the first-portion top surface is vertically separated from a first-patterned-hard-mask-layer top surface of the first patterned hard mask layer by a first pad thickness, wherein the second contact trenches extend in the second direction corresponding with the contact-edge features and overlap with the first contact trenches; and
etching the first contact portions in and through the first contact trenches of the first patterned hard mask layer to extend the first contact portions into the underlying layers below the first patterned hard mask layer to form the third contact trenches, such that each of the third contact trenches is defined by contact-trench sidewalls comprising first contact sidewalls patterned by the first contact trenches of the first patterned hard mask layer and second contact sidewalls patterned by the second contact trenches of the first overlying layers.
